(19) United States
(12) Patent Application Publication
(10) Pub. No.: US 2024/0421206 A1
(43) Pub. Date: Dec. 19, 2024

(54) SEMICONDUCTOR DEVICE

(71) Applicant: Samsung Electronics Co., Ltd., Suwon-si (KR)

(72) Inventors: Seonkyu Shin, Suwon-si (KR); Yongjin Kim, Suwon-si, (KR); Sanghoon Ahn, Suwon-si, (KR); Minkyoung Lee, Suwon-si, (KR)

(21) Appl. No.: 18/663,186

(22) Filed: May 14, 2024

(30) Foreign Application Priority Data
Jun. 16, 2023 (KR) 10-2023-0077602

(51) Int. Cl. H01L 29/423; H01L 29/06; H01L 29/417; H01L 29/66; H01L 29/775; H01L 29/786

(52) U.S. Cl. CPC H01L 29/42392; H01L 29/0673; H01L 29/41733; H01L 29/6656; H01L 29/775; H01L 29/78696

(57) ABSTRACT

A semiconductor device includes an active pattern extending on a substrate in a first direction; first and second lower channel layers in a first region and a second region of the active pattern, respectively; first and second upper channel layers on the first and second lower channel layers, respectively; a first source/drain pattern connected to the first and second lower channel layers; an isolation insulating layer on surfaces of the first source/drain pattern in the second direction, where a thickness of opposing edge portions of the isolation insulating layer when viewed in cross section along the first direction is smaller than a thickness of a central portion therebetween; a second source/drain pattern connected to the first and second upper channel layers; and an interlayer insulating layer on the second source/drain patterns and on the isolation insulating layer.

### CROSS-REFERENCE TO RELATED APPLICATION(S)

This application claims benefit of priority to Korean Patent Application No. 10-2023-0077602 filed on Jun. 16, 2023, in the Korean Intellectual Property Office, the disclosure of which is incorporated herein by reference in its entirety.

### FIELD

The present disclosure relates to a semiconductor device.

### BACKGROUND

With an increase in demand for high performance, high speed, and/or multifunctionalization of semiconductor devices, the degree of integration of semiconductor devices is increasing. In order to overcome limitations of operating characteristics due to a reduction in a size of metal oxide semiconductor FETs (planar MOSFETs), efforts are being made to develop semiconductor devices including a gate-all-around type field effect transistor (GAAFET) including a finFET including a fin-type channel and nanosheets surrounded by a gate.

### SUMMARY

An aspect of the present disclosure provides a semiconductor device having improved electrical characteristics and reliability.

According to an aspect of the present disclosure, a semiconductor device includes an active pattern extending on a substrate in a first direction; a device isolation layer on the substrate and defining the active pattern; first and second lower channel layers in first and second regions of the active pattern, respectively, and spaced apart from each other in a vertical direction that is perpendicular to an upper surface of the substrate; first and second upper channel layers on the first and second lower channel layers, respectively, and spaced apart from each other in the vertical direction; a first gate structure crossing the first region of the active pattern in a second direction, intersecting the first direction, and on the first lower channel layers and the first upper channel layers; a second gate structure crossing the second region of the active pattern in the second direction, and on the second lower channel layers and the second upper channel layers; a first source/drain pattern between the first and second gate structures and connected to the first and second lower channel layers; an isolation insulating layer on surfaces of the first source/drain pattern in the second direction and extending to an upper surface of the device isolation layer, wherein a thickness of opposing edge portions of the isolation insulating layer is smaller than a thickness of a central portion therebetween when viewed in cross section along the first direction; a second source/drain pattern between the first and second gate structures and connected to the first and second upper channel layers; and an interlayer insulating layer on the second source/drain patterns and on the isolation insulating layer.

According to an aspect of the present disclosure, a semiconductor device includes an active pattern extending on a substrate in a first direction; first and second channel structures sequentially stacked on the active pattern, wherein the first and second channel structures include a plurality of first and second channel layers, respectively, that are stacked to be spaced apart from each other in a vertical direction that is perpendicular to an upper surface of the substrate; an intermediate insulation pattern between the first and second channel structures; a gate structure crossing the active pattern in a second direction, intersecting the first direction, and on the plurality of first and second channel layers; a pair of first source/drain patterns on portions of the active pattern on opposing sides of the gate structure, and connected to opposing ends of the plurality of first channel layers, respectively; an isolation insulating layer having a plurality of insulating films stacked on the first source/drain patterns, respectively, wherein a first thickness of opposing edge portions thereof in the first direction is smaller than a second thickness of a portion thereof between the opposing edge portions; a pair of second source/drain patterns respectively connected to opposing ends of the plurality of second channel layers on the opposing sides of the gate structure; and an interlayer insulating layer on the isolation insulating layer, and on the second source/drain patterns.

According to an aspect of the present disclosure, a semiconductor device includes an active pattern extending on a substrate in a first direction; first and second lower channel layers in first and second regions of the active pattern, respectively, and spaced apart from each other in a vertical direction that is perpendicular to an upper surface of the substrate; first and second upper channel layers on the first and second lower channel layers, respectively, and spaced apart from each other in the vertical direction; a first intermediate insulation pattern between the first lower channel layers and the first upper channel layers; a second intermediate insulation pattern between the second lower channel layers and the second upper channel layers; a first gate structure crossing the first region of the active pattern in a second direction, intersecting the first direction, and on the first lower channel layers and the first upper channel layers; a second gate structure crossing the second region of the active pattern in the second direction, and on the second lower channel layers and the second upper channel layers; a first source/drain pattern between the first and second gate structures and connected to the first and second lower channel layers; an isolation insulating layer including a first insulating film on an upper surface of the first source/drain pattern, and at least one second insulating film stacked on the first insulating film and having opposing ends that are spaced apart from the first and second intermediate insulation patterns along the first direction; and a second source/drain pattern between the first and second gate structures, and connected to the first and second upper channel layers.

An isolation insulating layer according to an example embodiment of the present disclosure may repeatedly form a topological selective film to cover a surface of a lower source/drain pattern without exposure, thereby providing a stable separation structure from an upper source/drain pattern.

Advantages and effects of the present application are not limited to the foregoing content and may be more easily understood with reference to specific example embodiments as described in the present disclosure.

### BRIEF DESCRIPTION OF THE DRAWINGS

The above and other aspects, features, and advantages of the present disclosure will be more clearly understood from the following detailed description, taken in conjunction with the accompanying drawings, in which:

FIG. 1 is a plan view illustrating a semiconductor device according to an example embodiment of the present disclosure;

FIG. 2 is a cross-sectional view taken along line I-I′ of the semiconductor device of FIG. 1;

FIGS. 3A and 3B are cross-sectional views taken along line II1-II1′ and line II2-II2′ of the semiconductor device of FIG. 1, respectively;

FIG. 4 is a partially enlarged view illustrating part “A” of the semiconductor device of FIG. 2;

FIGS. 5A and 5B are plan views illustrating a semiconductor device according to various example embodiments (including variations of an isolation insulating layer) of the present disclosure;

FIGS. 6, 7A, and 7B are cross-sectional views illustrating a semiconductor device according to example embodiments of the present disclosure;

FIG. 8 is a cross-sectional view illustrating a semiconductor device according to an example embodiment of the present disclosure;

FIGS. 9A, 9B, 9C, 9D, 9E, and 9F are cross-sectional views illustrating certain processes (including forming a first source/drain pattern) in a method of manufacturing a semiconductor device according to an example embodiment of the present disclosure;

FIGS. 10A, 10B, 10C, 10D, 10E, and 10F are cross-sectional views illustrating another part of a manufacturing method of a semiconductor device (including forming an isolation insulating layer) according to an example embodiment of the present disclosure;

FIG. 11 is a graph illustrating a change in etching rate according to plasma treatment in accordance with an example embodiment of the present disclosure; and

FIGS. 12A, 12B, and 12C are cross-sectional views illustrating other processes (including forming a second source/drain pattern) in a method of manufacturing a semiconductor device according to an example embodiment of the present disclosure.

### DETAILED DESCRIPTION OF EMBODIMENTS

Hereinafter, example embodiments of the present disclosure will be described with reference to the accompanying drawings. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly on” or “in direct contact” or “directly connected,” no intervening components or layers are present.

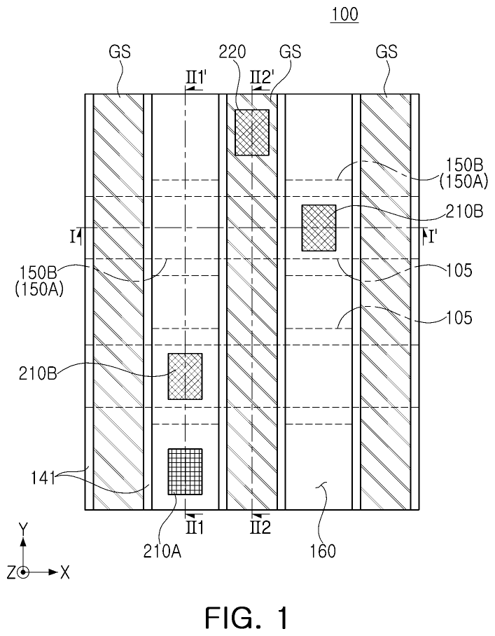

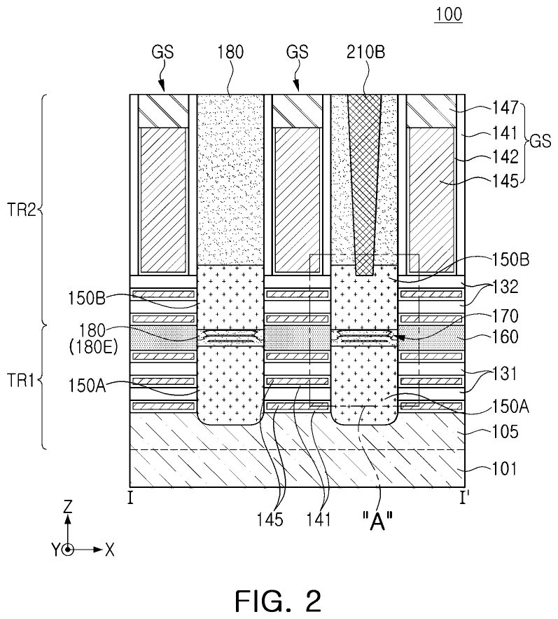

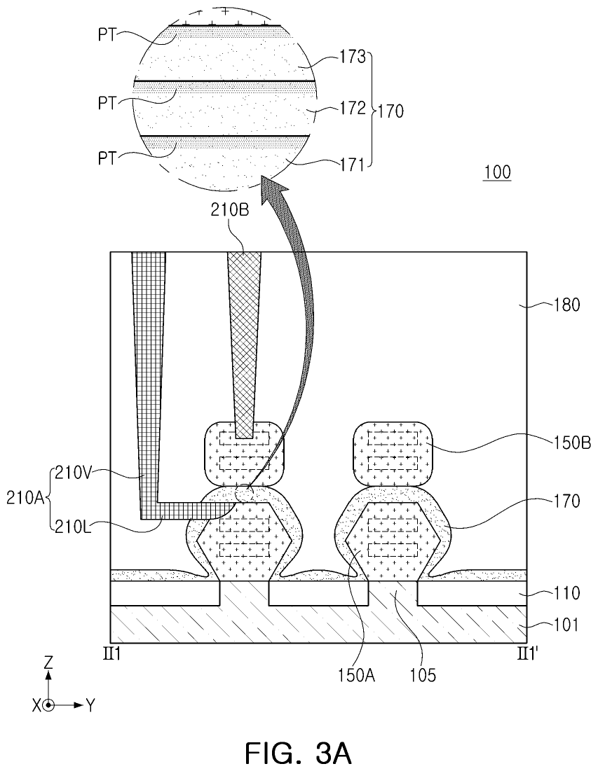

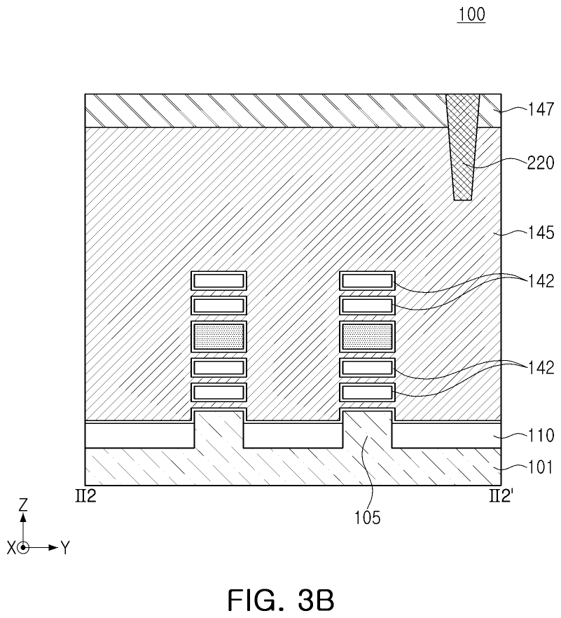

FIG. 1 is a plan view illustrating a semiconductor device according to an example embodiment of the present disclosure, FIG. 2 is a cross-sectional view taken along line I-I′ of the semiconductor device of FIG. 1, and FIGS. 3A and 3B are cross-sectional views taken along line II1-II1′ and line II2-II2′ of the semiconductor device of FIG. 1, respectively.

Referring to FIGS. 1, 2, 3A, and 3B, a semiconductor device 100 includes active patterns 105 extending on a substrate 101 in a first direction (e.g., an X-direction), first channel layers 131 (also referred to as “lower channel layers”) spaced apart from each other on regions of the active patterns 105 in a direction (e.g., a Z-direction), perpendicular to an upper surface of the substrate 101, second channel layers 132 (also referred to as “upper channel layers”) spaced apart from each other on the first channel layers 131 in the perpendicular direction (e.g., the Z-direction), and gate structures GS crossing the regions of the active patterns 105 to extend in a second direction (e.g., the Y-direction), intersecting the first direction (e.g., the X-direction) and surrounding the first channel layers 131 and the second channel layers 132. The term “surround” or “cover” or “fill” as may be used herein may not require completely surrounding or covering or filling the described elements or layers, but may, for example, refer to partially surrounding or covering or filling the described elements or layers.

Referring to the example of FIG. 1, the active patterns 105 include two active patterns, and the gate structures GS include three gate structures crossing the regions of the two active patterns 105, but the present disclosure is not limited thereto.

The substrate 101 may include a semiconductor material, for example, a Group IV semiconductor, a Group III-V compound semiconductor, or a Group II-VI compound semiconductor. For example, the Group IV semiconductor may include silicon (Si), germanium (Ge), or silicon germanium (SiGe). The substrate 101 may include a bulk wafer, an epitaxial layer, or a silicon on insulator (SOI) layer.

As illustrated in FIG. 1, the active pattern 105 may have a fin-shaped structure extending from the substrate 101 in the first direction (e.g., the X-direction). As illustrated in FIGS. 3A and 3B, a device isolation layer 110 may define the active pattern 105 in the substrate 101. The device isolation layer 110 may be disposed on the substrate 101, and a portion of the active pattern 105 may protrude from or may otherwise be exposed at an upper surface of the device isolation film 110. The device isolation layer 110 may be formed by, for example, a shallow trench isolation (STI) process. The device isolation layer 110 may include an insulating material. For example, the device isolation layer 110 may include, for example, silicon oxide, silicon nitride, silicon oxynitride, or a combination thereof.

As illustrated in FIG. 2, the semiconductor device 100 according to an example embodiment of the present disclosure may include a first transistor structure TR1 and a second transistor structure TR2 stacked on each of the regions of the active patterns 105. Each of the first and second transistor structures TR1 and TR2 in accordance with this embodiment may be a so-called Multi-Bridge Channel FET (MBCFET™) including a gate structure surrounding the first channel layers 131 and the second channel layers 132 disposed on the active pattern 105. The first transistor structures TR1 may be one of an N-type MOSFET and a P-type MOSFET, respectively, and the second transistor structures TR2 may be one of a P-type MOSFET and an N-type MOSFET. In some example embodiments, the first and second transistor structures TR1 and TR2 may be P-type MOSFET and N-type MOSFET, respectively.

In an example embodiment of the present disclosure, the first and second transistor structures TR1 and TR2 may be configured to share one gate structure GS.

Specifically, referring to FIGS. 2, 3A, and 3B, the first transistor structure TR1 may include first channel layers 131 stacked on an active pattern 105, a gate electrode 145 surrounding the first channel layers 131, first source/drain patterns 150A (also referred to as “lower source/drain patterns”) connected to the first channel layers 131 on one side or on opposing sides of the gate electrode 145, and a gate insulating film 142 between the first channel layers 131 and the gate electrode 145.

Similarly, the second transistor structure TR2 may include second channel layers 132, the gate electrode 145 surrounding the second channel layers 132, second source/drain patterns 150B (also referred to as “upper source/drain patterns”) connected to the second channel layers 132 on both (e.g., opposing) sides of the gate electrode 145, and a gate insulating film 142 between the second channel layers 132 and the gate electrode 145.

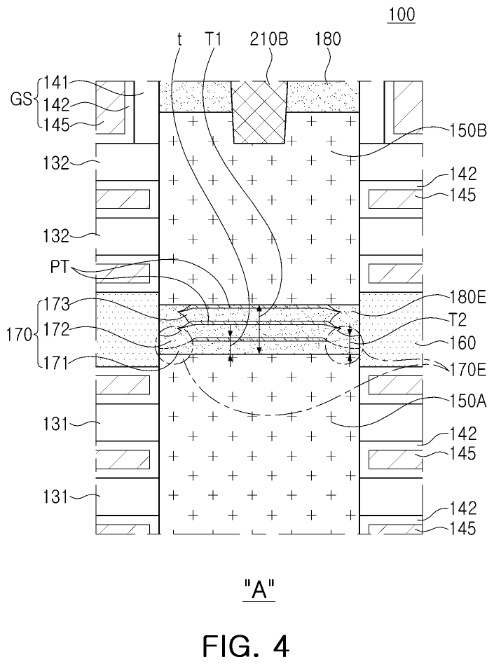

The semiconductor device 100 according to an example embodiment of the present disclosure may include an isolation insulating layer 170 disposed on the first source/drain patterns 150A to electrically separate the first source/drain patterns 150A and the second source/drain patterns 150B from each other. The isolation insulating layer 170 employed in this embodiment may provide an isolation structure that stably covers both (e.g., opposing) edge regions in the first direction (e.g., the X-direction) from the top surface of the first source/drain patterns 150A. The isolation insulating layer 170 may include a plurality of insulating films 171, 172 and 173. The structure and effect of the isolation insulating layer 170 in accordance with this embodiment will be described below with reference to FIG. 4 together with FIGS. 2 and 3A.

As described above, the first channel layers 131 are stacked to be spaced apart from each other on one portion of the active pattern 105 in the perpendicular direction (e.g., the Z-direction). A plurality of first channel layers 131 (e.g., two or three) may be provided, and each of the first channel layers 131 includes a semiconductor pattern. For example, the first channel layers 131 may include at least one of silicon (Si), silicon germanium (SiGe), and germanium (Ge). Similarly, a plurality of second channel layers 132 (e.g., two or three) may be provided, and each of the second channel layers 132 may include a semiconductor pattern. For example, the second channel layers 132 may include at least one of silicon (Si), silicon germanium (SiGe), and germanium (Ge).

An intermediate insulation pattern 160 is disposed on the top first channel layer among the first channel layers 131, and the second channel layers 132 are stacked in a direction perpendicular to the intermediate insulation pattern 160 (e.g., in the Z-direction). The intermediate insulation pattern 160 may be arranged to overlap the first channel layers 131 and the second channel layers 132 in the perpendicular direction (e.g., in the Z-direction). Components or layers described with reference to “overlap” in a particular direction may be at least partially obstructed by one another when viewed along a line extending in the particular direction or in a plane perpendicular to the particular direction. As described above, the stacked first channel layers 131 and the stacked second channel layers 132 may be separated by the intermediate insulation pattern 160.

The intermediate insulation pattern 160 includes an insulating material, and may include, for example, at least one of silicon nitride, silicon oxynitride, or silicon carbonitride. The intermediate insulation pattern 160 may be a single insulating material layer, but in some example embodiments, the intermediate insulation pattern 160 may include a plurality of insulating material layers.

The first source/drain pattern 150A may be disposed in a recessed portion of the active pattern 105, on both (e.g., opposing) sides of the first channel layers 131. The first source/drain pattern 150A may be provided as a source region or a drain region of the first transistor structure TR1. The first source/drain pattern 150A may include an epitaxial portion grown from a surface of the recessed portion of the active pattern 105 and both (e.g., opposing) side surfaces of the first channel layer 131. Similarly, the second source/drain patterns 150B may be disposed on both (e.g., opposing) sides of the second channel layers 132 and may be provided as a source region or a drain region of the second transistor structure TR2. The second source/drain pattern 150B may include an epitaxial portion grown using both (e.g., opposing) side surfaces of the second channel layer 132 as a seed layer.

The first and second source/drain patterns 150A and 150B may include a semiconductor epitaxial portion such as silicon (Si). The first and second source/drain patterns 150A and 150B may include impurities of different types and/or concentrations. For example, when the first transistor structure TR1 is a P-type MOSFET, the first source/drain patterns 150A may include silicon germanium (SiGe) doped in a P-type, and when the second transistor structure TR2 is an N-type MOSFET, the second source/drain patterns 150B may include silicon (Si) doped in an N-type. Accordingly, cross-sections of the first and second source/drain patterns 150A and 150B in a second direction (e.g., a Y-direction) may have different shapes. For example, a cross-section of the first source/drain patterns 150A may have a pentagonal shape, and a cross-section of the second source/drain pattern 150B may have a polygonal shape with a gentle angle.

As described above, referring to FIGS. 2 and 3A, the isolation insulating layer 170 may be disposed on multiple surfaces of the first source/drain patterns 150A in the second direction (e.g., Y-direction), and may extend to an upper surface of the device isolation layer 110. Since the isolation insulating layer 170 is introduced for an isolation of the first and second source/drain patterns 150A and 150B, it may be mainly formed on an upper surface of the first source/drain patterns, but as illustrated in FIG. 3A, the isolation insulating layer 170 may be formed relatively thin on other surfaces of the first source/drain patterns 150A, that is, on side surfaces thereof and a lower surface adjacent thereto, by a deposition process (e.g., an ALD process). FIG. 4 is a partially enlarged view illustrating part “A” of FIG. 2.

Referring to FIG. 4, an isolation insulating layer 170 has a cross-sectional structure in which a thickness T2 on both (e.g., opposing) edge portions 170E in the first direction (e.g., the X-direction) is smaller than a thickness T1 of a central portion therebetween. The isolation insulating layer 170 in accordance with this example embodiment may have a relatively thin thickness T2 of the both edge portions 170E in the first direction (e.g., the X-direction), but the isolation insulating layer 170 may sufficiently cover both (e.g., opposing) edge regions of an upper surface of the first source/drain patterns 150A by the edge portions 170E in the first direction (e.g., the X-direction), thereby ensuring stable isolation of the first and second source/drain patterns 150A and 150B.

The isolation insulating layer 170 includes a plurality of insulating films 171, 172 and 173. Even if the plurality of insulating films 171,172 and 173 include the same material, each of the plurality of insulating films 171,172 and 173 has a portion PT (e.g., impurity removal) whose upper surface is reformed by plasma treatment, and accordingly, the insulating film 171 may be visually distinguished from other insulating films 172 and 173 formed thereon. The isolation insulating layer 170 may include, for example, silicon oxide, silicon oxynitride, silicon carbonitride, or silicon nitride. The isolation insulating layer 170 may include a first insulating film 171 covering an upper surface of the first source/drain patterns 150A, and second and third insulating films 172 and 173 sequentially stacked on the first insulating film 171. In this example embodiment of the present disclosure, the isolation insulating layer 170 is illustrated as including three insulating layers, but in some example embodiments, the isolation insulating layer 170 may include two or more other insulating layers (e.g., four or more).

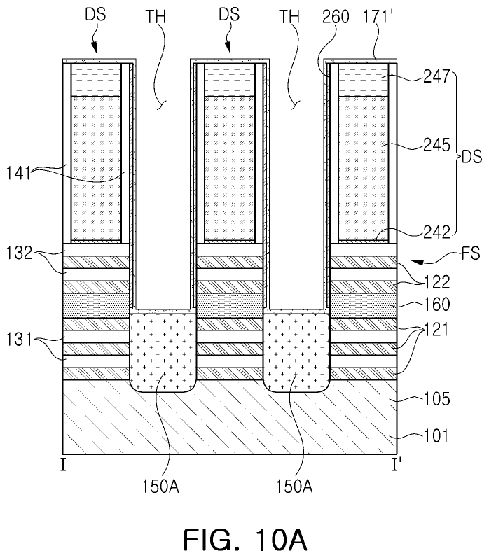

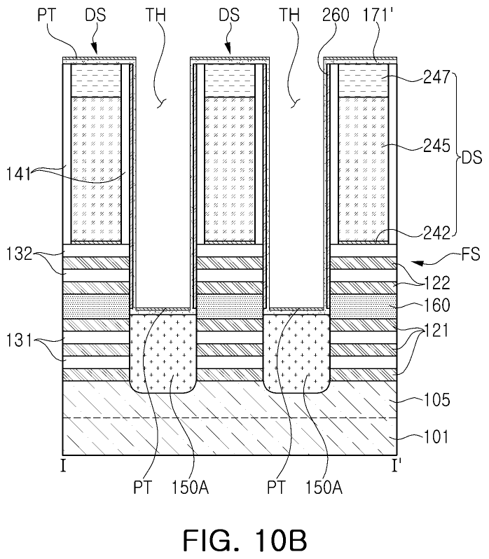

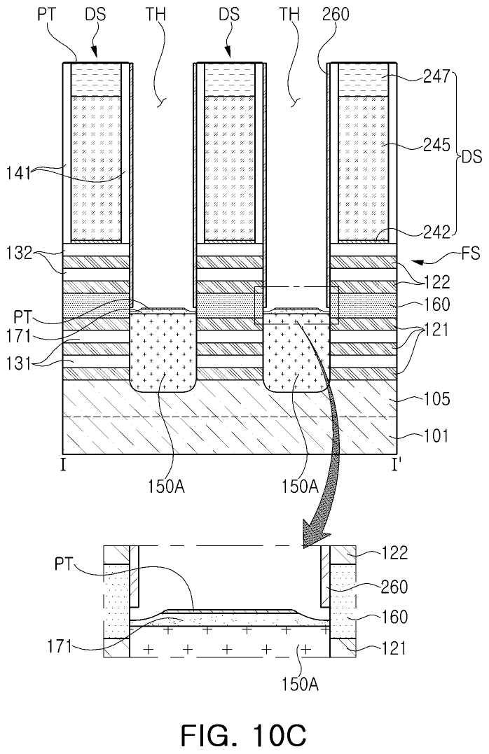

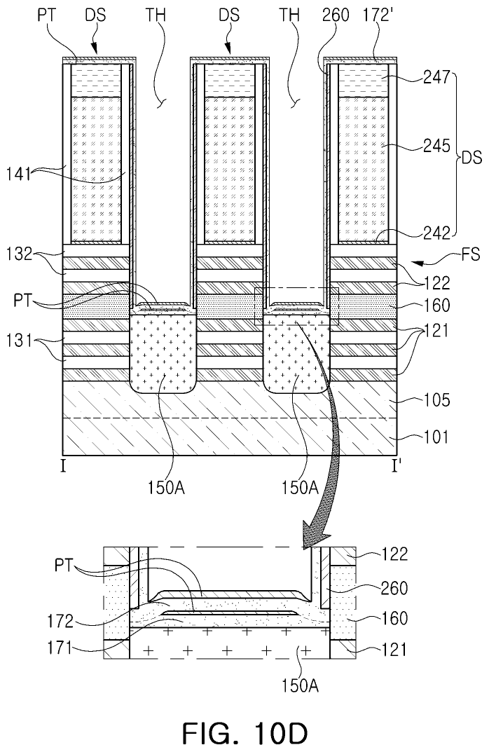

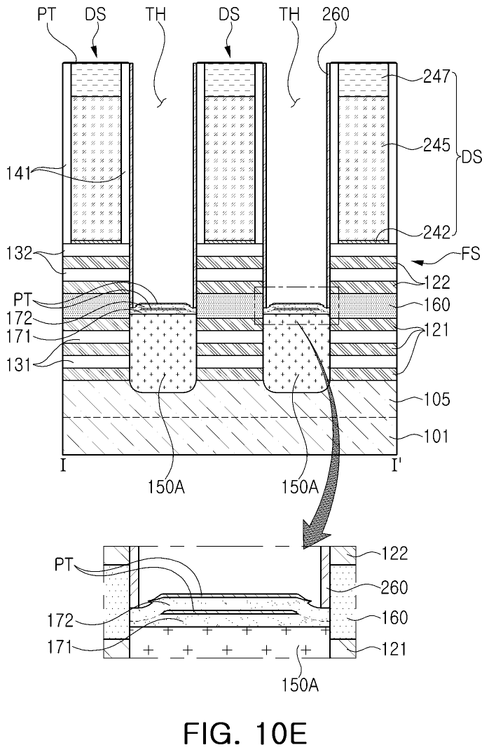

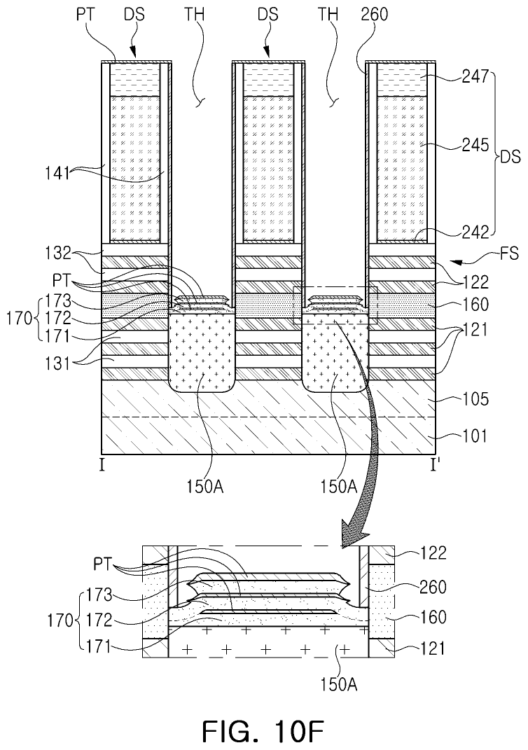

Referring to FIG. 4, an edge portion remaining when the first insulating film 171 is formed in edge portions 170E of the isolation insulating layer 170 may be a thin portion indicated by a dotted line (see FIG. 10C), and entire edge portions 170E of the isolation insulating layer 170 may further include edge portions remaining when other insulating layers (e.g., second and third insulating films 172 and 173) are formed (see FIGS. 10D to 10F). Since the edge portions 170E do not have a reformed portion PT, a boundary between the insulating films 171, 172 and 173 may not be clearly distinguished.

In this manner, through the formation of a conformal insulating film, plasma treatment (topological improvement), selective removal (e.g., wet etching), and repeated performance of these processes, the isolation insulating layer 170 having reinforced edge portions 170E may be formed. A manufacturing process of the isolation insulating layer 170 in accordance with this example embodiment will be described below with reference to FIGS. 10A to 10F.

As illustrated in FIG. 4, at least a portion of both (e.g., opposing) side surfaces of the second and third insulating layers 172 and 173 in the first direction (e.g., the X-direction) may be spaced apart from the intermediate insulation patterns 160. Furthermore, the both side surfaces of the second and third insulating layers 172 and 173 may have a non-flat surface. Specifically, the both side surfaces of the second and third insulating layers 172 and 173 may have protruding portions. Since the protruding portions have reformed portions on an upper surface thereof, it may be understood as having a structure obtained by undercutting only a lower portion thereof during wet etching. Since both (e.g., opposing) ends of the second and third insulating layers 172 and 173 in the first direction (e.g., the X-direction), that is, protruding portions, are formed by different processes, they may not be disposed on the same line (i.e., may not be aligned with each other) in a perpendicular direction and may be offset from each other (e.g., in a horizontal direction).

In an example embodiment of the present disclosure, an upper surface of the isolation insulating layer 170 may be in contact with a lower surface of the second source/drain patterns 150B. A gap between the first and second source/drain patterns 150A and 150B may be defined by the thickness T1 of the central portion of the isolation insulating layer 170.

In an example embodiment of the present disclosure, as described above, the first and second transistor structures TR1 and TR2 may share one gate structure GS. A gate electrode 145 employed in this example embodiment may be provided as a common gate electrode surrounding first and second channel layers 131 and 132. A gate insulating film 142 may be provided between the second channel layers 132 and the gate electrode 145 as well as between the first channel layers 131 and the gate electrode 145. Similarly, the gate insulating film 142 may surround an intermediate insulation pattern 160 in the second direction (e.g., the Y-direction). The gate structure GS may further include gate spacers 141. The gate spacers 141 may be disposed on both (e.g., opposing) sidewalls of an electrode portion extending on an uppermost second channel layers 132 of the gate electrode 145 in the second direction (e.g., in the Y-direction). A gate capping layer 145 may be formed on a gate electrode portion between the gate spacers 141.

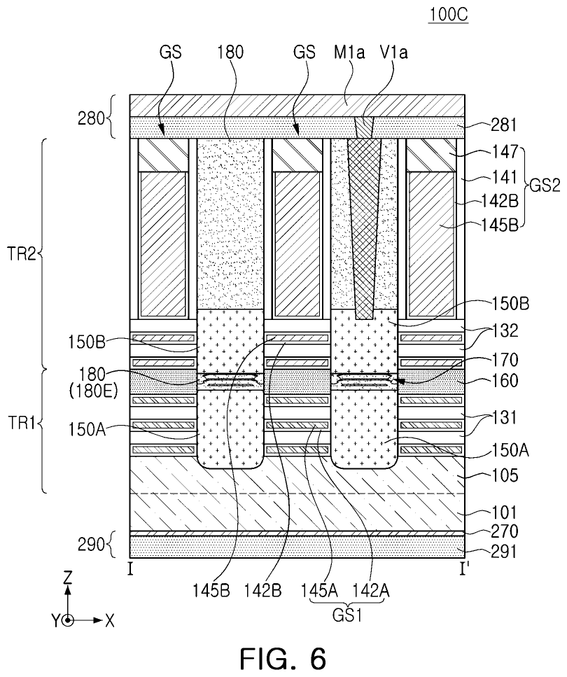

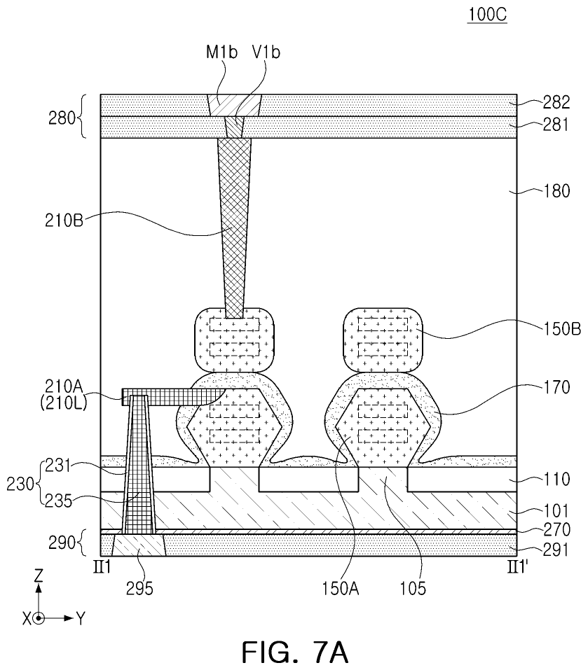

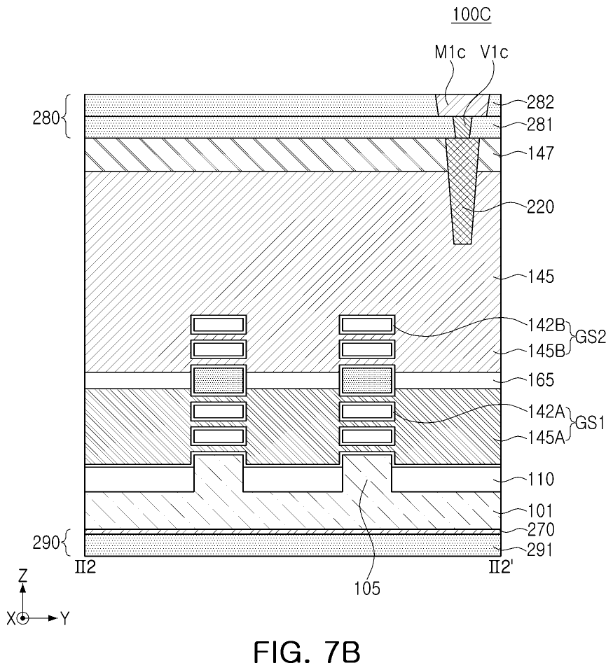

The gate electrode 145 in accordance with the present embodiment may include a conductive material. For example, the gate electrode 145 may include at least one of W, Ti, Ta, Mo, TiN, TaN, WN, TiON, TiAlC, TiAlN, and TaAlC. The gate electrode 145 may include a semiconductor material such as doped polysilicon. Each of the common gate electrodes 145 may be comprised of two or more multilayers. In some example embodiments, a first gate electrode 145A and a second gate electrode 145B may include different conductive materials (see FIGS. 6, 7A, and 7B).

For example, each of the gate insulating films 142 may include an oxide, a nitride, or a high-K material. The high-K material may refer to a dielectric material having a dielectric constant higher than that of a silicon oxide film (SiO₂), and the high-K material may refer to, for example, any one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and prascodymium oxide (Pr₂O₃).

For example, the gate spacers 141 may include at least one of silicon oxide, silicon nitride, and silicon oxynitride. In some example embodiments, the gate spacers 141 may include a multilayer structure. The gate capping layer 147 may include, for example, silicon nitride, silicon oxynitride, silicon carbonitride, or silicon oxycarbonitride.

The semiconductor device 100 according to an example embodiment of the present disclosure may cover the second source/drain patterns 150B and may include an interlayer insulating layer 180 disposed on the isolation insulating layer 170. In this example embodiment, referring to FIGS. 2 and 4, the interlayer insulating layer 180 may have a portion 180E extending to both (e.g., opposing) edge portions 170E of the isolation insulating layer 170 below a second source/drain pattern 150B. In an example embodiment of the present disclosure, the extending portion 180E of the interlayer insulating layer 170 may fill a space of the both edge portions 170E of the isolation insulating layer 170 and the second source/drain patterns 150B.

The interlayer insulating layer 180 may be silicon oxide. For example, the interlayer insulating layer 180 may be Spin-on Hardmask (SOH), Flowable oxide (FOX), Tonen SilaZen (TOSZ), undoped Silica Glass (USG), Borosilica Glass (BSG), PhosphoSilaca Glass (PSG), BoroPhosphoSilica Glass (BPSG), Plasma Enhanced Tetra Ethyl Ortho Silicate (PETEOS), Fluoride Silicate Glass (FSG), high density plasma (HDP) oxide, plasma enhanced oxide (PEOX), Flowable CVD (FCVD) oxide or combinations thereof. The interlayer insulating layer 180 may be formed using chemical vapor deposition (CVD), a flowable-CVD process, or a spin coating process.

As illustrated in FIGS. 1 to 3B, the semiconductor device 100 according to an example embodiment of the present disclosure may further include a lower contact structure 210A connected to the first source/drain region 150A, an upper contact structure 210B connected to the second source/drain regions 150B, and a gate contact structure 220 connected to the gate electrode 145.

The upper contact structure 210B may be connected to the second source/drain patterns 150B in the interlayer insulating layer 180, and the gate contact structure 220 may be connected to the gate electrode 145 in the interlayer insulating layer 180. The lower contact structure 210A is connected to the first source/drain pattern 150A in the interlayer insulating layer 180. Specifically, the lower contact structure 210A may include a parallel contact portion 210L extending in the parallel direction (e.g., the Y-direction) of the upper surface of the substrate 101, and a perpendicular contact portion 210V connected to the parallel contact portion 210L and extending in a direction (e.g., the Z-direction), perpendicular to the upper surface of the substrate 101. An interlayer insulating layer 180 may formed to be divided into a first interlayer insulating layer covering a first source/drain pattern, and a second interlayer insulating layer covering a second source/drain pattern on the first interlayer insulating layer, the parallel contact portion 210L may be disposed on the first interlayer insulating layer so as to be connected to the first source/drain pattern 150A, and after forming the second interlayer insulating layer, the perpendicular contact portion 210V may be formed to be connected to the parallel contact portion 210L by penetrating through the second interlayer insulating layer. For example, contact structures 210A, 210B and 220 may include at least one of titanium nitride (TiN), tantalum nitride (TaN), tungsten nitride (WN), tungsten carbon nitride (WCN), titanium (Ti), tantalum (Ta), tungsten (W), copper (Cu), aluminum (Al), cobalt (Co), ruthenium (Ru), and molybdenum (Mo).

In the isolation insulating layer 170 in accordance with an example embodiment of the present disclosure, edge portions 170E thereof have a thickness T2that is thinner than a thickness T1of a center portion between the edge portions 170E in a cross-section in the first direction (e.g., the X-direction) or the second direction (e.g., the Y-direction), but the edge portions 170E may have a sufficient thickness T2 for electrical isolation by repeated formation of additional insulating layers 172 and 173. As described above, the isolation insulating layer 170 may have various structures depending on the conditions (thickness or number) of each insulating film, plasma treatment conditions, and/or etching process conditions.

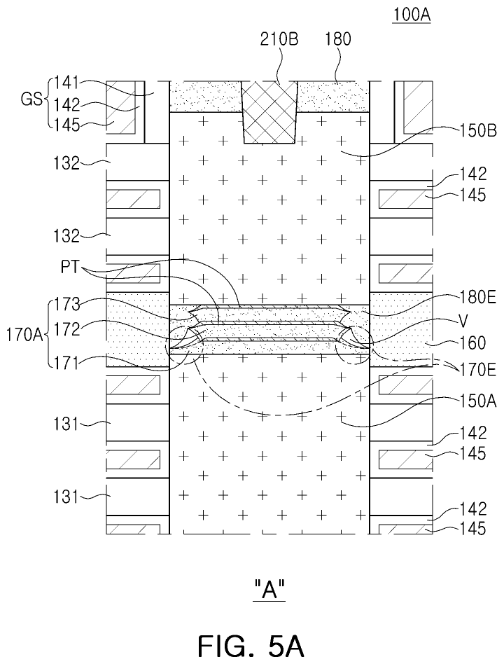

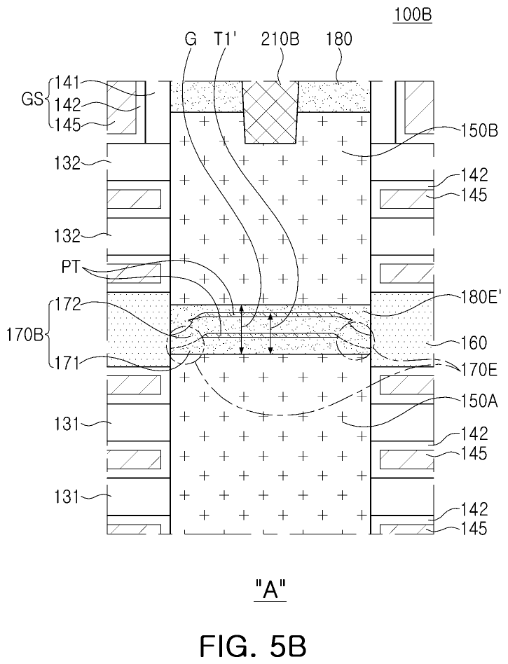

FIGS. 5A and 5B illustrate various types or shapes of isolation insulating layers that can be provided in accordance with an example embodiment of the present disclosure. Cross-sections of FIGS. 5A and 5B may be understood as partially enlarged view of region “A” of FIG. 2 (similar to FIG. 4), and semiconductor devices 100A and 100B illustrated in FIGS. 5A and 5B may be understood by referring to the description of the components identical to or similar to those of the semiconductor device 100 illustrated in FIGS. 1 to 4 unless otherwise described.

First, referring to FIG. 5A, a semiconductor device 100A according to an example embodiment of the present disclosure includes an isolation insulating layer 170A having different types or shapes of edge portions. The isolation insulating layer 170A used in this example embodiment may include three insulating films 171, 172 and 173, similarly to the previous example embodiment. Each of the insulating films 171, 172 and 173 may include the same material, and may include a portion PT reformed by plasma treatment on an upper surface thereof. The isolation insulating layer 170A may include a first insulating film 171 covering an upper surface of first source/drain patterns 150A, and second and third insulating films 172 and 173 sequentially stacked on the first insulating film 171.

Furthermore, similarly to the previous example embodiment, an interlayer insulating layer 180 may have an extending portion 180E below a second source/drain pattern 150B, and the extending portion 180E may partially fill or extend on edge portions 170E (i.e., a space between the isolation insulating layer 170A and an intermediate insulation pattern 160) of the isolation insulating layer 170A, but unlike the previous example embodiment, voids V that are not completely filled may remain. The voids V may be generated by formation conditions of the interlayer insulating layer 180 and/or a shape of side surfaces of the second and third insulating layers 172 and 173.

Referring to FIG. 5B, a semiconductor device 100B according to an example embodiment of the present disclosure includes an isolation insulating layer 170B having two insulating films 171 and 172, unlike the previous example embodiment. Each of the insulating films 171 and 172 may include the same material as each other, similarly to the previous example embodiment, and an upper surface thereof may include a portion PT reformed by plasma treatment. The isolation insulating layer 170B may include a first insulating film 171 covering an upper surface of the first source/drain patterns 150A and a second insulating film 172 stacked on the first insulating film 171.

Furthermore, unlike the previous example embodiments, the isolation insulating layer 170B employed in this example embodiment may have a thickness T1′ smaller than a gap G between the first and second source/drain patterns 150A and 150B. The interlayer insulating layer 180 has an extending portion 180E below the second source/drain pattern 150B, and the extending portion 180E may fill not only on a space on edge portions 170E of the isolation insulating layer 170 but also in a space between the first and second source/drain patterns 150A and 150B.

FIGS. 6, 7A, and 7B are cross-sectional views illustrating a semiconductor device according to example embodiments of the present disclosure.

Referring to FIGS. 6, 7A, and 7B, a semiconductor device 100C according to an example embodiment of the present disclosure may be understood as being similar to the semiconductor device 100 illustrated in FIGS. 1 to 4, except that a gate structure GS is separated into first and second gate structures GS1 and GS2, a first lower contact 210A includes a through electrode 250 extending from a lower surface of a substrate 101, and first and second wiring structures 280 and 290 are additionally provided. Furthermore, components of this example embodiment may be understood by referring to the description of components identical to or similar to the semiconductor device 100 illustrated in FIGS. 1 to 4 unless otherwise described.

Gate structures in accordance with an example embodiment of the present disclosure include first gate structures GS1 related to a first transistor structure TR1 and a second gate structure GS2 related to a second transistor structure TR2. Specifically, unlike the common gate electrode 145 of the previous example embodiment, the semiconductor device 100C according to an example embodiment of the present disclosure may include first and second gate electrodes 145A and 145B separated by an inter-gate insulating film 165. As illustrated in FIG. 7B, the inter-gate insulating layer 165 may be disposed between the first gate electrode 145A surrounding first channel layers 131 and the second gate electrode 145B surrounding second channel layers 132. At least a portion of the inter-gate insulating film 165 may be disposed to overlap an intermediate insulation pattern 160 in a parallel direction. The second gate electrode 145B may include a conductive material different from that of the first gate electrode 145A. Similarly, the first gate insulating film 142A and the second gate insulating film 142B may include different dielectric layers or a combination thereof.

A lower contact 210A in accordance with an example embodiment of the present disclosure may include a parallel contact portion 210L connected to a first source/drain pattern 150A, and a through electrode 230 extending from a lower surface of a substrate 101 and connected to the parallel contact portion 210L. The through electrode 230 may include a contact plug 235, and an insulating liner 231 surrounding the contact plug 235 for insulation from the substrate 101. For example, the contact plug 235 may include Cu, Co, Mo, Ru, W, or alloys thereof. For example, the insulating liner 231 may contain SiO₂, SiN, SiCN, SiC, SiCOH, SION, Al₂O₃, AlN, or combinations thereof.

The semiconductor device 100C according to an example embodiment of the present disclosure may include a first wiring structure 280 (or referred to as a “front wiring structure”) disposed on an interlayer insulating layer 180 and a second wiring structure 290 (or referred to as a “rear wiring structure”) disposed on a lower surface of the substrate 101. The first wiring structure 280 may also be applied to the semiconductor device 100 according to the previous example embodiment, but for convenience of explanation, it may be understood as being omitted in FIGS. 2, 3A, and 3B.

Referring to FIGS. 6, 7A, and 7B, the first wiring structure 280 includes first wiring insulating layers 281 and 282 disposed on the interlayer insulating layer 180 and first to third upper wiring lines M1a, M1b and M1c disposed within the first wiring insulating layer 281 and 282. The first to third upper wiring lines M1a, M1b and M1c may be connected to an upper contact structures 210B or gate contact structures 220 through metal vias V1a, V1b and Vc, respectively.

Similarly, the second wiring structure 290 includes a second wiring insulating layer 291 disposed on the lower surface of the substrate 101, and lower wiring lines 295 placed within the second wiring insulating layer 291. The lower wiring line 295 may be a power supply line, and the first to third upper wiring lines M1a, M1b and M1c may be signal lines. In an example embodiment, an etching stop layer 270 may be disposed between the substrate 101 and the second wiring insulating layer 291. The etching stop layer 270 may be used in a process of forming the lower wiring line 295. In this example embodiment, the first to third upper wiring lines M1a, M1b and M1c and the lower wiring line 295 may extend in the first direction (e.g., the X-direction).

The first and second wiring insulating layers 281 and 291 in accordance with an example embodiment of the present disclosure may include silicon oxide, silicon oxynitride, SiOC, SiCOH, or combinations thereof. For example, upper wiring lines M1a, M1b and M1c, lower wiring lines 295, and metal vias V1a, V1b and V1c may include copper or a copper-containing alloy. In some example embodiments, the upper wiring lines M1a, M1b and M1c may be formed together using a dual-damascene process with each of the metal vias V1a, V1b and V1c.

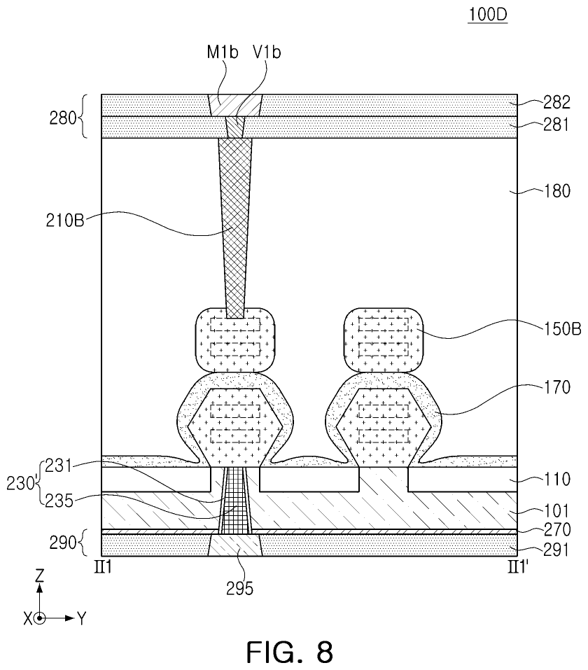

FIG. 8 is a cross-sectional view illustrating a semiconductor device according to an example embodiment of the present disclosure, and may be understood as a cross-sectional view corresponding to FIG. 7B.

Referring to FIG. 8, a semiconductor device 100D according to an example embodiment of the present disclosure may be understood as being similar to the semiconductor device 100C illustrated in FIGS. 6, 7A, and 7B, except that the semiconductor device 100D has another type of through electrode 230′. Furthermore, components of this embodiment may be understood by referring to the description of components identical to or similar to those of the semiconductor device 100C illustrated in FIGS. 6, 7A, and 7B unless otherwise described.

In an example embodiment of the present disclosure, a lower contact connected to a first source/drain pattern 150A may be replaced by a through electrode 230′. The through electrode 230′ according to this example embodiment extends from a lower surface of a substrate 101. Specifically, the through electrode 230′ may penetrate through an active pattern 105 and be directly connected to a lower surface of the first source/drain pattern 150A. The through electrode 230′ may include a contact plug 235, and an insulating liner 231 surrounding the contact plug 235 for insulation from the substrate 101.

As described above, the semiconductor device according to an example embodiment of the present disclosure may be advantageously applied to various structures. Specifically, an isolation insulating layer according to an example embodiment of the present disclosure may cover first source/drain patterns without exposing surfaces of the first source/drain patterns by repeatedly forming a topological selective film, and may ensure stable electrical insulation between the first and second source/drain patterns. The term “expose” may be used herein to describe relationships between elements and/or certain intermediate processes in fabricating a semiconductor device.

Hereinafter, a method of manufacturing a semiconductor device according to an embodiment of the present invention will be described.

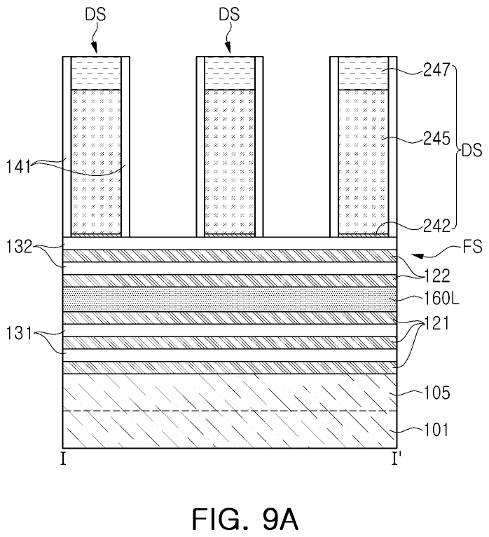

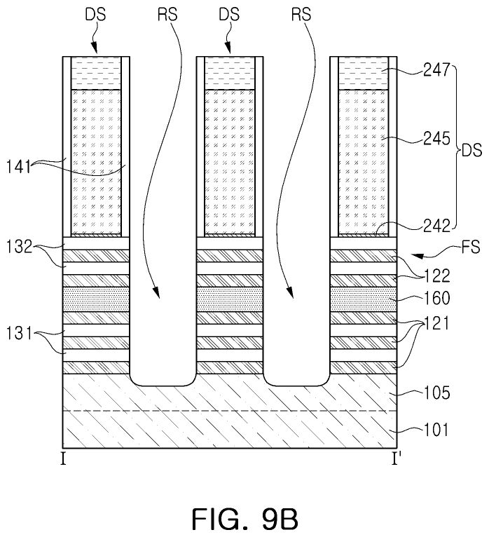

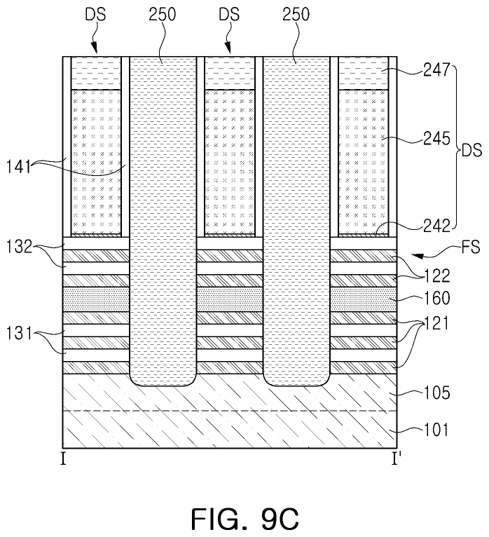

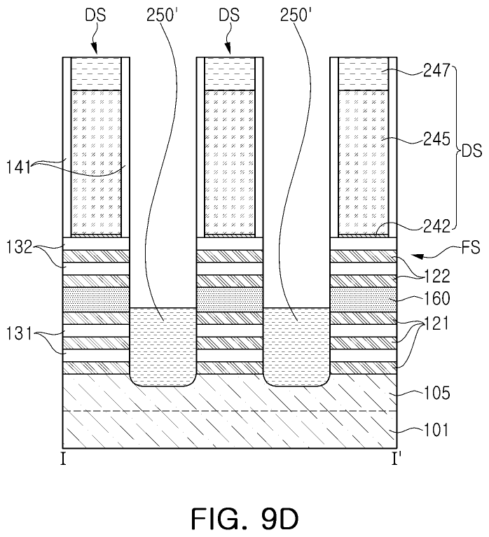

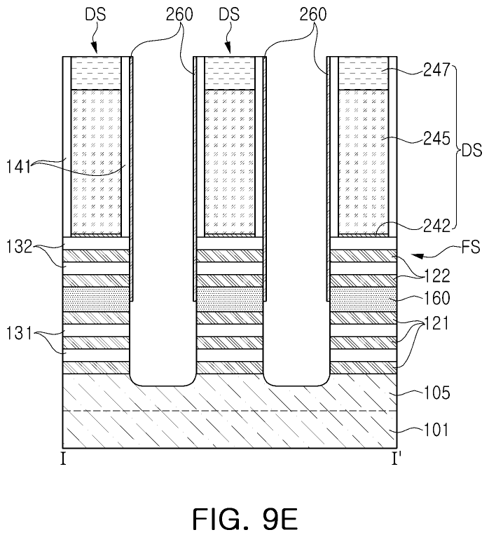

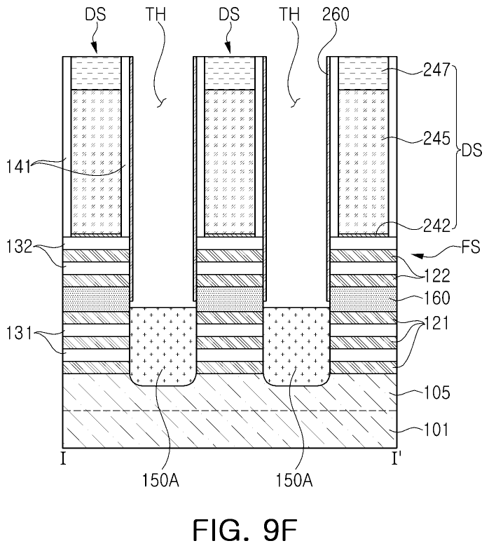

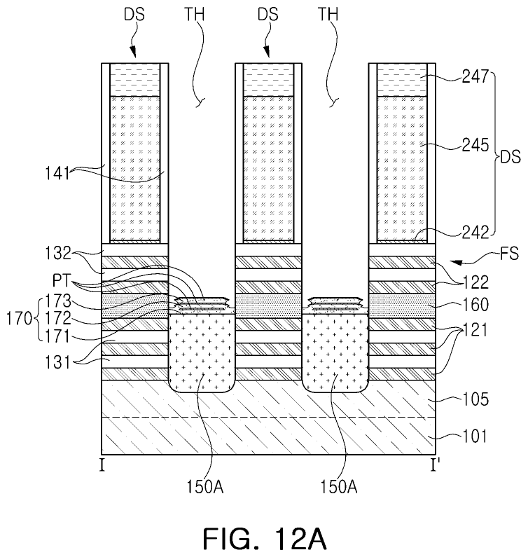

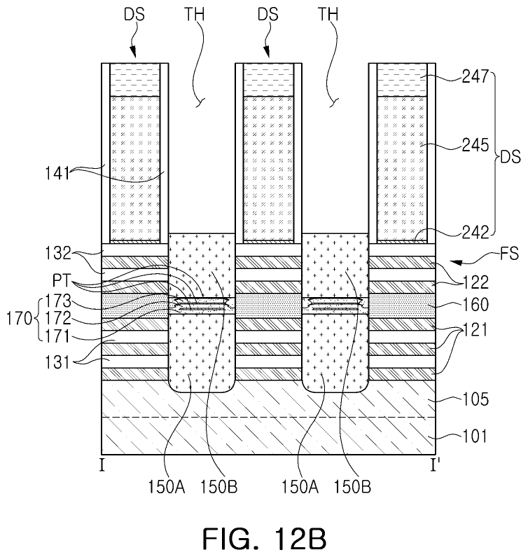

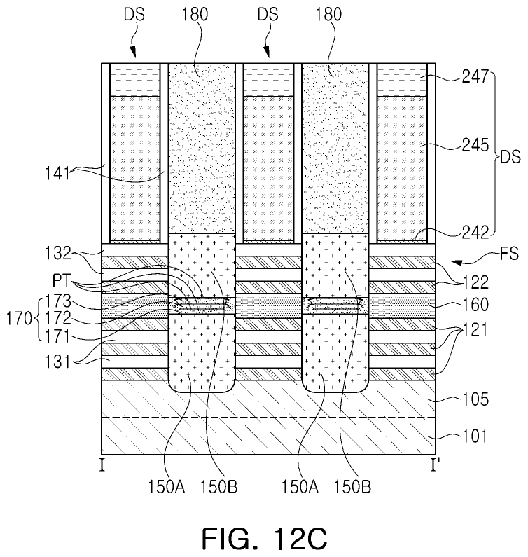

FIGS. 9A to 9F are cross-sectional views for explaining a process of forming a first source/drain pattern as certain processes in a method of manufacturing a semiconductor device according to an example embodiment of the present disclosure, FIGS. 10A to 10F are cross-sectional views for explaining a process of forming an isolation insulating layer according to an example embodiment of the present disclosure as other processes in a method of manufacturing a semiconductor device according to an example embodiment of the present disclosure, and FIGS. 12A to 12C are cross-sectional views for explaining a process of forming a second source/drain pattern as another process in a method of manufacturing a semiconductor device according to an example embodiment of the present disclosure.

Referring to FIG. 9A, a fin-type stack structure FS is disposed on an active pattern 105 extending in a first direction (e.g., the X-direction) of a substrate 101, and a dummy gate structure DS is included in a second direction (e.g., the Y-direction) so as to cross the fin-type stack structure FS.

The fin-type stacked structure FS may include a first stack structure in which first sacrificial layers 121 and a first channel layer 131 are alternately stacked, a second stack structure in which second sacrificial layers 122 and second channel layers 132 are alternately stacked on the first stack structure, and an intermediate insulating layer 160L between the first and second stacked structures. The intermediate insulating layer 160L may be provided as an intermediate insulation pattern 160. The first channel layer 131 and the second channel layer 132 may include a semiconductor material for forming channels of the first and second transistor structures. Each of the first channel layer 131 and the second channel layer 132 may include, for example, a semiconductor material including at least one of silicon (Si), silicon germanium (SiGe), and germanium (Ge). The first channel layer 131 and the second channel layer 132 may include impurities, but the present disclosure is not limited thereto. The intermediate insulating layer 160L may include at least one of SiO, SiN, SiCN, SiOC, SiON, SiOCN, SiBN, and SiBCN.

The first and second sacrificial layers 121 and 122 may include different materials to have etching selectivity from the first and second channel layers 131 and 132. In some example embodiments (e.g., when the first and second gate electrodes are formed of different gate electrode materials), the first sacrificial layer 121 may include different materials to have etching selectivity with the second sacrificial layers 122. For example, the first and second sacrificial layers 121 and 122 may include silicon germanium (SiGe), and the first and second channel layers 131 and 132 may include silicon (Si). Furthermore, the first and second sacrificial layers 121 and 122 and the first and second channel layers 131 and 132 may have a thickness in the range of about 1 to 100 nm, respectively. In some example embodiments, the number of layers of the first and second channel layers 131 and 132 alternately stacked with the first and second sacrificial layers 121 and 122 may be variously changed.

Dummy gate structures DS and gate spacers 141 may be formed on the fin-type stack structure FS. Each of the dummy gate structures DS may be a sacrificial structure providing a space for forming gate structures GS to be formed in a subsequent process. The dummy gate structures DS may have a line shape crossing the fin-type stack structures FS and extending in the second direction (e.g., the Y-direction), and may be arranged to be spaced apart from each other in the first direction (e.g., X-direction).

The dummy gate structures DS may include first and second dummy material layers 242 and 245 and a mask pattern layer 247 which are sequentially stacked. The first and second dummy material layers 242 and 245 may be patterned using the mask pattern layer 247. The first and second dummy material layers 242 and 245 may be an insulating layer and a conductive layer, respectively, but the present disclosure is not limited thereto, and the first and second dummy material layers 242 and 245 may be formed as a single layer. In some example embodiments, the first dummy material layer 242 may include silicon oxide, and the second dummy material layer 245 may include polysilicon. The mask pattern layer 247 may include silicon oxide and/or silicon nitride.

The gate spacers 141 may be formed on both (e.g., opposing) sidewalls of the dummy gate structures DS. The gate spacers 141 may be formed through anisotropic etching after forming a film having a uniform thickness along an upper surface and a side surface of a substrate on which the dummy gate structures DS are formed. The gate spacers 141 may be formed of a low dielectric constant material, and may include, for example, at least one of SiO, SiN, SiCN, SiOC, SiON, and SiOCN.

Then, referring to FIG. 9B, a recess portion RS may be formed by partially removing portions of the fin-type stacked structure FS between the dummy gate structures DS up to an active pattern 105. The process may be performed by removing an exposed region of the fin-type stacked structure FS using the dummy gate structures DS and the gate spacers 141 as masks. Through the process, the first and second channel layers 131 and 132 may have a desired length in the first direction (e.g., the X-direction). Portions of the active pattern 105 and side surfaces of the first channel layers 131 exposed by the recess portion RS may be provided as regions for forming first source/drain pattern, and side surfaces of the second channel layers 132 may be provided as regions for forming second source/drain pattern.

Referring to FIG. 9C, a gap-fill insulating layer 250 may fill the recess region RS.

A process of forming the gap-fill insulating layer 250 may be obtained by depositing a first insulating material so as to fill spaces between the dummy gate structures DS, and performing a planarization process such as chemical mechanical polishing (CMP). For example, the gap-fill insulating layer 250 may be a silicon oxide such as spin on hardmask (SOH).

Referring to FIG. 9D, the gap-fill insulating layer 250 may be recessed, and a gap-fill insulating pattern 250′ corresponding to a first source/drain pattern may remain in each of recess portions (RS).

A recess process of the gap-fill insulating layer 250 may be performed by a process such as an etch-back. A gap-fill insulation pattern 250′ may be formed to have an upper surface level covering at least side surfaces of the first channel layers 131. In an example embodiment of the present disclosure, the upper surface level of the gap-fill insulation pattern 250′ may be formed to overlap the intermediate insulation pattern 160 in a parallel direction.

Referring to FIG. 9E, a blocking insulating layer 260 may be formed on exposed sidewalls of the dummy gate structure DS, and the gap-fill insulation pattern 250′ may be removed to open a region to form the first source/drain pattern.

The blocking insulating layer 260 conformally forms a second insulating material over an entire region. Specifically, a second insulating material film is formed not only on the sidewalls of the dummy gate structure DS, but also on an upper surface of the dummy gate structures DS and a bottom surface (i.e., an upper surface of the gap-fill insulation pattern 250′) thereof. The second insulating material film may include a dielectric material that inhibits epitaxial growth. For example, the second insulating material film may include silicon nitride (SiN), silicon oxynitride (SiON), or silicon carbonitride (SiCN). By applying an anisotropic etching process such as dry etching, portions disposed on upper surfaces of the dummy gate structures DS and an upper surface of the gap-fill insulating pattern 250′ may be removed from the second insulating material film, and as illustrated in FIG. 9E, the blocking insulating layer 260 may remain in the exposed sidewalls of the dummy gate structure DS. The blocking insulating layer 260 may be provided to cover the sidewall of the dummy gate structure DS including side surfaces of the second channel layers 132.

The gap-fill insulation pattern 250′ may be removed to open a region to form the first source/drain pattern. That is, a recessed portion of the active pattern and side surfaces of the first channel layers may be exposed.

Referring to FIG. 9F, a process of forming a first source/drain pattern 150A may be performed.

A desired first source/drain patterns 150A may be formed by growing an epitaxial layer from an open recess portion RS and side surfaces of first channel layers 131. On the other hand, growth of the epitaxial layer may be suppressed in a portion in which the blocking insulating layer 260 is formed. In an example embodiment of the present disclosure, a lower end of the blocking insulating layer 260 may be somewhat spaced apart from the first source/drain pattern 150A. A portion of an isolation insulating layer 170 may be disposed in a separated region in a subsequent process. The isolation insulating layer 170 covering a surface of the first source/drain patterns 150A may be formed through processes illustrated in FIGS. 10A to 10F.

A process of forming an isolation insulating layer 170 according to an example embodiment of the present disclosure may start from a process of conformally depositing a first insulating film 171′ as illustrated in FIG. 10A.

The present process may be performed by an atomic deposition process (ALD). The first insulating film 171′ used in the present process may include a material selectively etched with a blocking insulating layer 260. For example, the first insulating film 171′ may include SiO₂. The first insulating film 171′ may be formed not only on an upper surface of a first source/drain pattern 150A, but also on sidewalls (i.e., on the blocking insulating layer 260) of dummy gate structures DS and upper surfaces of the dummy gate structures DS. A thickness of the first insulating film 171′ may be determined in consideration of a gap between the first and second source/drain patterns 150A and 150B, the number of additional insulating layers, and/or other process conditions. Although the present disclosure is not limited thereto, the thickness of the first insulating film 171′ may be 3 nm to 10 nm. The thickness of the first insulating film 171′ deposited in the present process may be greater than a thickness of a first insulating film 171 of a final isolation insulating layer 170.

Referring to FIG. 10B, an anisotropic plasma treatment is applied to the first insulating film 171′ to assign selectivity for topologically subsequent wet etching.

Parallel components of the first insulating film 171′, that is, first components on the first source/drain pattern 150A and second components on the dummy gate structure DS that extend parallel to the substrate 101, may have a portion reformed by plasma treatment. The plasma treatment may be variously applied according to a material of the first insulating film 171′. For example, in the case of silicon oxide, the present process may be performed by an anisotropic plasma treatment process using Ar plasma, DCS (dichlorosilane), NH₃ plasma, or a combination thereof.

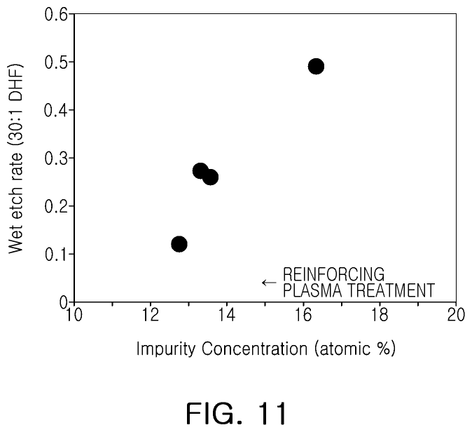

In the present process, a plasma-treated region of the first insulating film 171′ may have a portion PT in which a film quality is reformed by removing impurities (e.g., C, etc.). Referring to FIG. 11, it may be seen that as the plasma treatment is enhanced, impurities are reduced and an etching rate is changed from 0.5 to 0.1 during DHF wet etching. In this manner, the etching rate of one first insulating film 171′ may be significantly changed depending on whether it is plasma treated. In the present process, plasma-treated parallel components (i.e., components or portions thereof extending parallel to the substrate 101) may have a sufficient wet etching selectivity with non-plasma-treated perpendicular components (i.e., components or portions thereof extending perpendicular to the substrate 101).

In this specification, the term “topological selective film” refers to a material film that can be selectively etched through or responsive to a local plasma treatment on the insulating film, as illustrated in FIG. 11.

Referring to FIG. 10C, as perpendicular components of the first insulating film 171′ are selectively removed by applying wet etching, the parallel portions of the first insulating film 171′, that is, a final first insulating film 171, may remain. For example, the present process may be performed using a dilute HF (DHF) wet process. In this process, portions (i.e., perpendicular components) of the first insulating film 171′ disposed on the blocking insulating layer 260 may be removed, and the first insulating film part 170 disposed on the first source/drain pattern 150A may remain due to the reformed portion PT.

In the present process, in the process of removing some or all perpendicular parts of the first insulating film 171′ by wet etching, edge portions of the first insulating film 171 may be additionally removed to reduce a thickness thereof, as compared to a central portion protected by the modified portion PT. The reformed portion PT of the first insulating film 171 may also be somewhat etched to have a thickness reduced from an initially formed thickness of the first insulating film 171′.

The processes described in FIGS. 10A, 10B, and 10C may be repeated as many times as necessary to form an isolation insulating layer 170 having a desired thickness.

Specifically, referring to FIG. 10D, a second insulating film 172′ is conformally formed similarly to the process of FIG. 10A, and an anisotropic plasma treatment process is applied similarly to the process of FIG. 10B. As a result, parallel components of the second insulating film 172′, a first component disposed in a first insulating film 171, and a second component disposed on an upper surface of a dummy gate structure DS may have reformed portions PT to have selectivity with other portions (i.e., perpendicular components). On the other hand, the second insulating film 172′ may be formed to have a relatively large thickness in a corner portion (or an edge portion) disposed adjacently to an intermediate insulation pattern 160, and some of the edge portions may be covered by the reformed portion PT of the second insulating film 172′.

Referring to FIG. 10E, similarly to the process of FIG. 10C, as perpendicular components of the second insulating film 172′ are selectively removed by applying wet etching, parallel portions of the second insulating film 172′, that is, a final second insulating film 172, may remain. Specifically, as described above, since the edge portions of the second insulating film 172 have a relatively large thickness and are partially covered by the reformed portion PT, significant amounts of portions may remain in a process of removing the perpendicular components of the second insulating film 172′. Edge regions of first source/drain patterns 150A in the first direction may be stably covered by increasing a thickness of an entire edge portion of the second insulating film 172.

Referring to FIG. 10F, a third insulating layer 173 may be additionally formed on a second insulating film 172 by additionally repeating the processes described in FIGS. 10A, 10B, and 10C. Through this process, an isolation insulating layer 170 having a desired thickness may be formed.

In the present process, in a process of removing some or all perpendicular portions of a first insulating film 171′ by wet etching, edge portions of a first insulating film 171 may be additionally removed to reduce a thickness thereof as compared to a central portion protected by a reformed portion PT. The reformed portion PT of the first insulating film 171 may also be somewhat etched to have a thickness reduced from an initially formed thickness of the first insulating film 171′.

FIGS. 12A to 12C are cross-sectional views illustrating further processes (forming a second source/drain pattern) in a method of manufacturing a semiconductor device according to an example embodiment of the present disclosure.

Referring to FIG. 12A, side surfaces of second channel layers 132 may be opened by removing a blocking insulating layer 260 from a sidewall of a dummy gate structure DS. Referring to FIG. 12B, a selective epitaxial growth process may be performed from the side surfaces of the second channel layers 132 to grow a second source/drain patterns 150B. In this process, the second source/drain patterns 150B may be prevented from coming into contact with a first source/drain patterns 150A by an isolation insulating layer 170. Referring to FIG. 12C, an interlayer insulating layer 180 may be formed on the isolation insulating layer 170 to cover the second source/drain patterns 150B. The interlayer insulating layer 180 may be formed to cover an upper surface of the dummy gate structure DS and may then be flattened or planarized to remove a mask pattern layer 247 of the dummy gate structure DS by applying a CMP process. In the CMP process, the remaining parallel components formed on the upper surface of the dummy gate structure DS may also be removed in a process of forming the isolation insulating layer 170.

After removing the mask pattern layer 247, first and second dummy material layers 242 and 245 of the dummy gate structure DS may be removed, and after selectively removing first and second sacrificial layers 121 and 122, a process of forming a gate insulating layer 142, a gate electrode 145 and a gate capping layer 147 may be performed, thereby manufacturing the semiconductor device 100 illustrated in FIGS. 1 to 4.

Spatially relative terms such as ‘on,’ ‘above,’ ‘over,’ ‘upper,’ ‘upper portion,’ ‘upper surface,’ ‘below,’ ‘under,’ ‘lower,’ ‘lower portion,’ ‘lower surface,’ ‘side surface,’ and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features, such that the spatially relative descriptors used herein may be interpreted accordingly.

The present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. A semiconductor device comprising:
an active pattern extending on a substrate in a first direction;
a device isolation layer on the substrate exposing the active pattern;
first and second lower channel layers in first and second regions of the active pattern, respectively, and spaced apart from each other in a vertical direction that is perpendicular to an upper surface of the substrate;
first and second upper channel layers on the first and second lower channel layers, respectively, and spaced apart from each other in the vertical direction;
a first gate structure crossing the first region of the active pattern in a second direction, intersecting the first direction, and on the first lower channel layers and the first upper channel layers;
a second gate structure crossing the second region of the active pattern in the second direction and on the second lower channel layers and the second upper channel layers;
a first source/drain pattern between the first and second gate structures and connected to the first and second lower channel layers;
an isolation insulating layer extending on surfaces of the first source/drain pattern in the second direction and extending to an upper surface of the device isolation layer, wherein a thickness of opposing edge portions of the isolation insulating layer is smaller than a thickness of a central portion therebetween when viewed in cross section along the first direction;
a second source/drain pattern between the first and second gate structures and connected to the first and second upper channel layers; and
an interlayer insulating layer on the second source/drain patterns and on the isolation insulating layer.

2. The semiconductor device of claim 1, wherein the isolation insulating layer comprises a first insulating film on an upper surface of the first source/drain pattern, and at least one second insulating film stacked on the first insulating film.

3. The semiconductor device of claim 2, wherein the at least one second insulating film is a plurality of second insulating films, and
opposing side surfaces of the plurality of second insulating films in the first direction are non-planar, respectively.

4. The semiconductor device of claim 2, wherein the at least one second insulating film is a plurality of second insulating films, and
opposing ends of the plurality of second insulating films in the first direction are not aligned with each other in the vertical direction.

5. The semiconductor device of claim 1, wherein an upper surface of the isolation insulating layer is in contact with a lower surface of the second source/drain pattern.

6. The semiconductor device of claim 5, wherein a portion of the interlayer insulating layer extends on at least one of the opposing edge portions of the isolation insulating layer in the first direction under the second source/drain pattern.

7. The semiconductor device of claim 5, further comprising a void under the second source/drain pattern and on at least one of the opposing edge portions of the isolation insulating layer in the first direction.

8. The semiconductor device of claim 1, wherein an upper surface of the isolation insulating layer is spaced apart from a lower surface of the second source/drain pattern, and a portion of the interlayer insulating layer extends therebetween.

9. The semiconductor device of claim 1, wherein the isolation insulating layer comprises silicon oxide.

10. The semiconductor device of claim 1, wherein each of the first and second gate structures comprises:
a gate electrode crossing the active pattern in the second direction, and on the first lower and upper channel layers or the second lower and upper channel layers,
a pair of gate spacers along opposing sidewalls of the gate electrode in the first direction, and
a gate insulating film between the gate electrode and the first lower and upper channel layers, or between the gate electrode and the second lower and upper channel layers.

11. The semiconductor device of claim 10, wherein the gate electrode comprises a lower gate electrode on the first and second lower channel layers and an upper gate electrode on the first and second upper channel layers, and
the gate insulating film comprises a first gate insulating film between the first and second lower channel layers and the lower gate electrode, and a second gate insulating film between the first and second upper channel layers and the upper gate electrode.

12. The semiconductor device of claim 1, further comprising:
a lower contact structure electrically connected to the first source/drain pattern; and
an upper contact structure electrically connected to the second source/drain pattern.

13. The semiconductor device of claim 12, wherein the lower contact structure is electrically connected to the first source/drain pattern by extending through the substrate from a lower surface of the substrate that is opposite the upper surface of the substrate.

14. A semiconductor device comprising:
an active pattern extending on a substrate in a first direction;
first and second channel structures sequentially stacked on the active pattern, wherein the first and second channel structures include a plurality of first and second channel layers, respectively, that are stacked to be spaced apart from each other in a vertical direction that is perpendicular to an upper surface of the substrate;
an intermediate insulation pattern between the first and second channel structures;
a gate structure crossing the active pattern in a second direction, intersecting the first direction, and on the plurality of first and second channel layers;
a pair of first source/drain patterns on portions of the active pattern on opposing sides of the gate structure, and connected to opposing ends of the plurality of first channel layers, respectively;
an isolation insulating layer having a plurality of insulating films stacked on the first source/drain patterns, respectively, wherein a first thickness of opposing edge portions thereof in the first direction is smaller than a second thickness of a portion thereof between the opposing edge portions;
a pair of second source/drain patterns connected to opposing ends of the plurality of second channel layers on the opposing sides of the gate structure, respectively; and
an interlayer insulating layer on the isolation insulating layer, and on the second source/drain patterns.

15. The semiconductor device of claim 14, wherein the plurality of insulating films comprises:
a first insulating film on respective upper surfaces of the first source/drain patterns; and
at least one second insulating film stacked on the first insulating film.

16. The semiconductor device of claim 15, wherein the at least one second insulating film is a plurality of second insulating films, and
opposing ends of each of the plurality of second insulating films in the first direction has a respective protruding portion.

17. The semiconductor device of claim 16, further comprising a void on at least one of the opposing edge portions of the isolation insulating layer in the first direction under respective lower surfaces of the second source/drain patterns.

18. The semiconductor device of claim 17, wherein a portion of the interlayer insulating layer extends along at least a portion of the void under the second source/drain pattern.

19. The semiconductor device of claim 14, wherein the second thickness of the isolation insulating layer is about 5 nm to 20 nm, and
respective thicknesses of central portions of the plurality of insulating films are about 2 nm to 5 nm.

20. A semiconductor device comprising:
an active pattern extending on a substrate in a first direction;
first and second lower channel layers in first and second regions of the active pattern, respectively, and spaced apart from each other in a vertical direction that is perpendicular to an upper surface of the substrate;
first and second upper channel layers on the first and second lower channel layers, respectively, and spaced apart from each other in the vertical direction;
a first intermediate insulation pattern between the first lower channel layers and the first upper channel layers;
a second intermediate insulation pattern between the second lower channel layers and the second upper channel layers;
a first gate structure crossing the first region of the active pattern in a second direction, intersecting the first direction, and on the first lower channel layers and the first upper channel layers;
a second gate structure crossing the second region of the active pattern in the second direction, and on the second lower channel layers and the second upper channel layers;
a first source/drain pattern between the first and second gate structures and connected to the first and second lower channel layers;
an isolation insulating layer comprising a first insulating film on an upper surface of the first source/drain pattern, and at least one second insulating film stacked on the first insulating film and having opposing ends that are spaced apart from the first and second intermediate insulation patterns along the first direction; and
a second source/drain pattern between the first and second gate structures, and connected to the first and second upper channel layers.
